(19) United States
(12) Patent Application Publication
(10) Pub. No.: US 2024/0379341 A1
(43) Pub. Date: Nov. 14, 2024

(54) METHOD OF MANUFACTURING SEMICONDUCTOR WAFERS AND METHOD OF MANUFACTURING SEMICONDUCTOR DEVICES

(71) Applicant: GlobalWafers Japan Co., Ltd., Kitakanbara-gun (JP)

(72) Inventors: Ken HAYAKAWA, Kitakanbara-gun (JP); Haruo SUDO, Kitakanbara-gun (JP)

(73) Assignee: GlobalWafers Japan Co., Ltd., Kitakanbara-gun (JP)

(21) Appl. No.: 18/660,383

(22) Filed: May 10, 2024

(30) Foreign Application Priority Data
May 11, 2023 (JP) 2023-078710

(51) Int. Cl. H01L 21/02; H01L 21/66

(52) U.S. Cl. CPC H01L 21/0201; H01L 22/20

(57) ABSTRACT

A method of manufacturing a semiconductor wafer by performing the RTA treatment for suppressing slips is provided. The method of manufacturing a semiconductor wafer according to the present invention includes a step of performing the RTA treatment on a semiconductor wafer 1, wherein, for example, a first correction for eliminating temperature variations of the entire wafer surface is performed throughout the entire process of heating and cooling in the RTA treatment, and further, in the cooling process, a second correction of +0.1° C. or more and +5.0° C. or less is performed to a part or the entire wafer outer circumference 1d, which is an outer region including the wafer periphery.

### TECHNICAL FIELD

The present invention relates to a method of manufacturing semiconductor wafers having a treatment process of rapid thermal annealing (RTA).

### BACKGROUND ART

A large number of grown-in defects exist on the surface and in the surface layer of a semiconductor wafer, which is obtained by slicing a semiconductor single crystal ingot grown by the Czochralski (CZ) method. Meanwhile, since semiconductor wafers are required to be almost defect-free on the surface and in the surface layer, the RTA treatment is conventionally performed, which is one of the methods to eliminate the defects on the surface and in the surface layer.

The heat treatment of rapid heating and the rapid cooling by the RTA treatment eliminates the defects on the surface and in the surface layer of semiconductor wafers, and also densely forms bulk micro-defects (BMD) in the bulk region. The BMD in the bulk region diffuses during the semiconductor device fabrication process and acts as a gettering site for metal impurities that can affect the characteristics of devices.

For example, as a method of manufacturing semiconductor wafers including the step of performing the RTA treatment, the patent literature 1 listed below discloses a method of forming BMD highly densely at the time of precipitation heat treatment thereafter, by subjecting the silicon wafer to the RTA treatment at a temperature of not less than 1300° C. and not more than 1400° C. in an oxidizing atmosphere and by leaving a large number of vacancies, point defects, in the bulk region of the silicon wafer.

In addition, as a heat treatment technique to inhibit slip due to the performance of the RTA treatment, Patent Literature 2 discloses a technique for heat treatment under conditions where the temperature of the contact area of the support member supporting the semiconductor wafer therewith is controlled to set to be 3 to 20 degrees lower than that of the central area of the semiconductor wafer, in the method of manufacturing semiconductor wafers having a step of performing the heat treatment with the RTA apparatus at a predetermined temperature.

### CITATION LIST

### Patent Literature

PTL 1: JA-A-2015-204326
PTL 2: JA-A-2002-164300

### SUMMARY OF INVENTION

### Technical Problem

PTL 1 above states that the RTA treatment is performed at a temperature of 1300° C. or higher and 1400° C. or lower in an oxidizing atmosphere. Meanwhile, when such an RTA treatment is performed, the temperature difference in the wafer plane and the stress due to the self-weight of the semiconductor wafer cause slips to occur. In particular, when the wafer support member is an edge ring supporting the semiconductor wafer from the backside peripheral side, slips tend to occur at the edge portion of the wafer because the stress due to the self-weight of the wafer and the thermal stress due to the temperature difference between the semiconductor wafer and the wafer support member act simultaneously at the contact position between the semiconductor wafer and the wafer support member.

In addition, to eliminate defects on the surface and the surface layer of the semiconductor wafers and to form BMD in the bulk portion, it is preferable to perform the RTA treatment at a temperature of 1300° C. or higher where rapid heating and rapid cooling are possible. When such an RTA treatment is performed, the effects of the slips due to the thermal stress increase particularly. Specifically, during the process of rapid cooling from the maximum temperature reached, the edge surface of the wafer is more easily heat-dissipated than the center of the wafer, and in addition, slips tend to occur due to the superposition of both the heat transfer from the wafer edge surface to the wafer support member and the stress due to the self-weight of the wafer.

In order to control the slip due to the thermal stress described above, the temperature distribution in the plane of the wafer must be controlled to be uniform. PTL 1 does not disclose the method of inhibiting the slip by performing the RTA treatment at a temperature of 1300° C. or higher; that is, the method of inhibiting the slip due to thermal stress. Since the slip described above is a cause of the defects of the device, heat treatment capable of inhibiting the slip is required.

PTL 2 describes that the temperature distribution is made such that the temperature difference between the central area and the periphery of the wafer is set within the range of 3° C. to 20° C. by gradually lowering the temperature from the central area to the periphery of the wafer, as a method of preventing the slip by controlling the temperature of the heat treatment. This method, however, cannot control the temperature distribution in the wafer plane to be uniform, and cannot achieve sufficient slip inhibition effects of the slip cannot be obtained as a countermeasure for slip inhibition due to thermal stress.

Not only for the semiconductor wafers but also for the manufacturing step of semiconductor devices from semiconductor wafers, slip prevention methods are required by implementing the RTA treatment.

The present invention is made in consideration of the above problems, and an object of the present invention is to provide a method of manufacturing semiconductor wafers to inhibit slips due to thermal stress by implementing the RTA treatment. Another object of the present invention is to provide a method of manufacturing semiconductor devices for inhibiting slips by implementing the RTA treatment.

### Solution to Problem

The method of manufacturing semiconductor wafers has a process for performing an RTA treatment, characterized in that a first correction using a first offset which is a temperature correction value for eliminating temperature variations over entire the wafer surface is performed throughout the processes from heating to cooling in the RTA treatment, and further, in the cooling process, the second correction is performed using a second offset which is a temperature correction value being set so that the temperature correction value for the wafer outer circumference, which is the wafer outer circumference region including the wafer periphery, is set to be relatively between +0.1° C. or more and +5.0° C. or less, compared to the temperature correction values for the wafer regions other than the wafer outer circumference. As an example, in the second correction, a correction of +0.1° C. or more to +5.0° C. or less is performed for a part or the entire wafer outer circumference.

In addition, the RTA treatment is desirably carried out under the conditions of holding at a maximum temperature reached of 1250° C. or higher for a period of 1 s or more to 60 s or less in an oxidizing atmosphere and of cooling down to 1000° C. or less at a cooling rate of 75° C./s or more and 120° C./s. In addition, the second correction is desirably performed within a period of at least 5 s of the elapsed time from the time of the start of cooling in the cooling process.

With the method of manufacturing semiconductor wafers according to the present invention, slips occurring from the wafer outer circumference of the wafer at the time of rapid cooling in the RTA treatment are inhibited even when the RTA treatment is performed at a temperature of 1300° C. or higher where the gettering performance against metal impurities that are diffused during the process of manufacturing semiconductor devices to affect on the device performance is ensured.

In the method of manufacturing semiconductor wafers according to the present invention, the RTA treatment is performed while the semiconductor wafer is placed on a wafer support member having a support surface inclined downwardly toward the inside, and the surface roughness of the semiconductor wafer in the vicinity of the contact position of the semiconductor wafer with the wafer support member is desirably 5.0 nm≤Ra≤30.0 nm. Furthermore, in the method of manufacturing wafers according to the present invention, the diameter of the wafer on which the RTA treatment is to be performed is desirably 300 mm or more and the wafer outer circumference is desirably the area within 10 mm or less from the periphery of the semiconductor wafer toward the center.

The method of manufacturing semiconductor devices according to the present invention is a method of manufacturing semiconductor devices having a process of performing the RTA treatment on semiconductor wafers, characterized in that a first correction using a first offset, which is a correction value of temperature to eliminate temperature variations across the wafer surface, is performed throughout the processes from heating to cooling in the RTA treatment, and further, in the cooling process, the second correction is performed using the second offset, which is a temperature correction value being set so that the temperature correction value for the wafer outer circumference, which is the wafer outer circumference including the wafer periphery, is set relatively between +0.1° C. or more and +5.0° C. or less, compared to the temperature correction values for the wafer regions other than the wafer outer circumference.

### Advantageous Effects of Invention

With the method of manufacturing semiconductor wafers according to the present invention, slips due to thermal stress by performing the RTA treatment can be inhibited.

### BRIEF DESCRIPTION OF DRAWINGS

FIGS. 1A-1C are a cross-sectional view schematically illustrating the method of manufacturing semiconductor wafers according to the present invention.

FIG. 2 is a cross-sectional view roughly illustrating an RTP apparatus.

FIGS. 3A-3C are a cross-sectional view schematically illustrating the method of manufacturing semiconductor wafers of Comparative Example 1.

FIG. 4 is a figure showing the measurement results by SIRD of the strain-area ratio of each silicon wafer subjected to the RTA treatment by the method of Experimental Examples 1 to 4 and Comparative Example 1.

### DESCRIPTION OF EMBODIMENTS

Embodiments of the method of manufacturing semiconductor wafers according to the present invention will be described in detail with reference to the drawings. The present invention is not limited by the embodiments.

### Method of Manufacturing Semiconductor Wafers

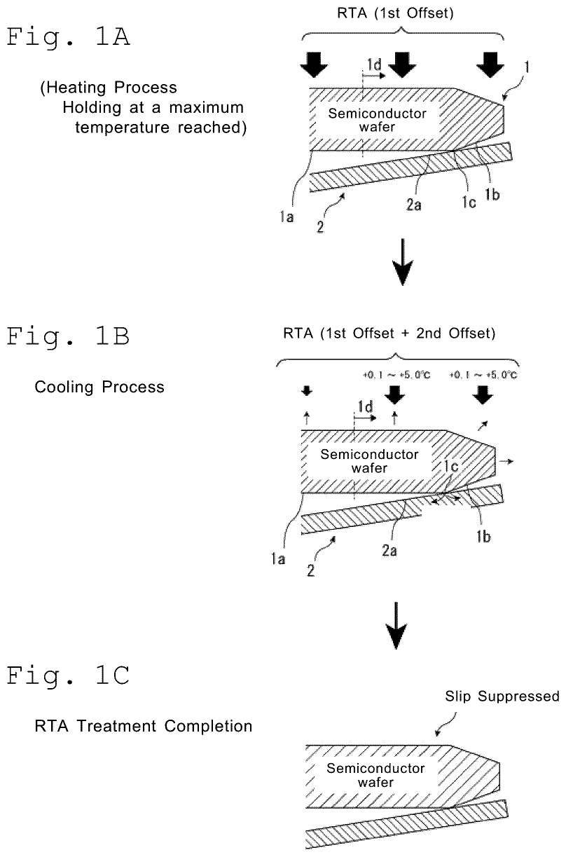

FIGS. 1A-1C are a cross-sectional view schematically illustrating the method of manufacturing semiconductor wafers (sometimes simply referred to as wafers) according to the present embodiment. The manufacturing method shown in FIGS. 1A-1C have a process of performing the RTA treatment on a semiconductor wafer 1, and, for example, the RTA treatment is performed in a state where the semiconductor wafer 1 is placed on a wafer support member 2 having a support surface 2a inclined downwardly toward the inside.

The method of manufacturing semiconductor wafers according to the present embodiment will be described in detail below. After obtaining a semiconductor single crystal ingot grown by the Czochralski method, the semiconductor single crystal ingot is sliced into a wafer-like shape with, for example, a wire saw (slicing). The semiconductor wafers obtained by slicing are subjected to the beveling process (beveling). The irregular layer formed during slicing is removed by the lapping process (lapping) and grinding process (grinding), and the flatness and roughness are improved. Then, the processing damage caused by the lapping and grinding processes is removed by an etching process.

In the present embodiment, a semiconductor wafer 1 in which an angle formed by the wafer backside 1a and backside bevel 1b is made obtuse as shown in FIGS. 1A-1C is produced by the above-described manufacturing processes of slicing, beveling, lapping, grinding, and etching in the recited order. In this embodiment, as an example, a semiconductor wafer 1 having a diameter of 300 mm is produced. At that time, the semiconductor wafer 1 is processed such that the boundary portion, or the apex 1c of the obtuse angle, of the wafer backside 1a and the backside bevel 1b is in contact with the support surface 2a when the semiconductor wafer 1 is placed on the support surface 2a, which is inclined downward toward the inside of the wafer support member 2.

Then, the RTA treatment shown in FIGS. 1A-1C is performed to the semiconductor wafer 1 produced by the manufacturing processes described above. The RTA treatment is performed under the condition of holding at a maximum temperature reached of 1250° C. or higher, or preferably 1300° C. or higher and 1350° C. or lower, for a period of 1 s or longer and 60 s or shorter in an oxidizing atmosphere and cooling to 1000° C. or less at a cooling rate of 75° C./s or more and 120° C./s or less. For example, in the RTA treatment in the method of manufacturing of the present embodiment, a first correction, in which the first offset is set in advance, is performed to eliminate the temperature variations across the wafer plane throughout the process from heating to cooling, and in addition, in the cooling process, a second correction, in which the second offset is set in advance, is performed using the second offset, which is the correction of the temperature that is set such that the temperature correction value for the wafer outer circumference id, which is the wafer outer circumference including the wafer periphery, is set relatively to +0.1° C. or more and +5.0° C. or less, more preferably +0.5° C. or more and +3.0° C. or less, and particularly preferably +1.0° C. or more and +1.5° C. or less, compared to the temperature correction values for the wafer regions other than the wafer outer circumference.

In addition, in the present embodiment, the surface of the semiconductor wafer subjected to the RTA treatment is mirror-polished after the RTA treatment described above.

For example, the contact area of the semiconductor wafer with the wafer support member 2 tends to increase due to the reduction of the surface roughness when the semiconductor wafer 1 is subjected to the RTA treatment after mirror polishing. As a result, slips tend to occur due to the welding of the semiconductor wafer with the wafer support member 2 in the RTA treatment at a temperature of 1250° C. or higher. Accordingly, in the present embodiment, in order to further reduce the slip due to the RTA treatment, the surface roughness of the semiconductor wafer 1 is made 5.0 nm≤Ra≤30.0 nm in the vicinity of the contact position of the semiconductor wafer 1 with the wafer support member 2 in the manufacturing process described above. Thereby the contact area of the semiconductor wafer 1 with the wafer support member 2 decreases and the slip due to welding is further reduced. For example, when the surface roughness Ra≤5.0 nm, the contact area of the semiconductor wafer 1 with the wafer support member 2 increases, and the slip due to welding is likely to occur, which is undesirable. When Ra≥30.0 nm, the wafer contact area becomes uneven because the surface of the semiconductor wafer is too rough, and the slip due to the self-weight stress is likely to occur, which is undesirable.

In the semiconductor wafer produced by the manufacturing method of semiconductor wafers according to the present embodiment, slips starting to occur from the wafer outer circumference (wafer edge surface) are inhibited when rapidly cooled in the RTA treatment even when the RTA treatment is performed at a temperature of 1300° C. or higher where the gettering performance against metal impurities is ensured.

The wafer outer circumference 1d to which the second correction is performed is, for example, the region within 10 mm toward the center from the periphery of the semiconductor wafer 1 as the outer circumference including the wafer periphery. When the wafer outer circumference 1d exceeds 10 mm, for example, slips may occur in the wafer center region of the wafer, which is undesirable.

Although there is no particular restriction on the diameter (size) of semiconductor wafer 1, the method of manufacturing semiconductor wafers of the present embodiment is useful, for example, as the method for manufacturing semiconductor wafers with a diameter of 300 mm or more.

### RTP Apparatus and RTA Treatment

The RTA treatment in the manufacturing method of the present embodiment will be further described in detail, with an example of an RTP apparatus (a heat treatment apparatus) 10 having a halogen lamp (e.g., a high-voltage tungsten halogen lamp) as a heat source.

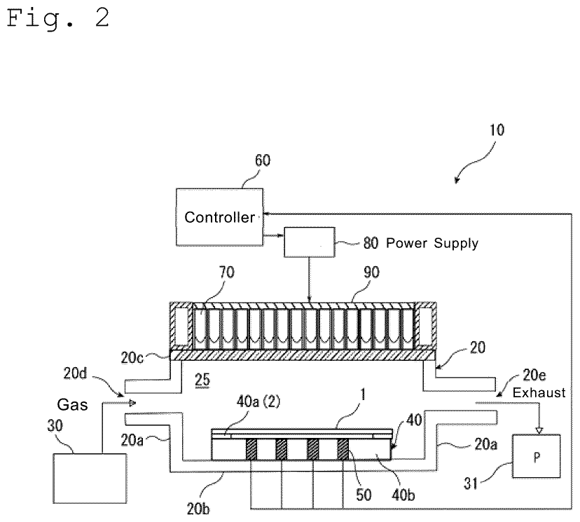

FIG. 2 is a cross-sectional view schematically illustrating an RTP apparatus 10 for performing the RTA treatment. The RTP apparatus 10 is provided with a chamber 20; the chamber 20 includes a chamber wall 20a, a chamber bottom 20b connected to the chamber wall 20a, and a quartz window 20c disposed above the chamber wall 20a.

The chamber wall 20a, the chamber bottom 20b, and the quartz window 20c which constitute the chamber 20 form a reaction space 25 for processing the semiconductor wafer 1 placed therein. A slit valve door (not shown) penetrating through the chamber wall 20a is provided in the RTP apparatus 10 for transferring the semiconductor wafer 1 into the reaction space 25.

The RTP apparatus 10 is provided with a gas inlet 20d formed on the chamber wall 20a, and the gas inlet 20d is connected to a gas supply source 30 that supplies one or more processing gases to the reaction space 25. In addition, the RTP apparatus 10 is provided with a gas outlet 20e formed on the chamber wall 20a, and the gas outlet 20e is connected to a vacuum pump (P) 31 for evacuating the reaction space 25 to the outside. Furthermore, the RTP apparatus 10 is provided with a wafer support 40 for supporting the semiconductor wafer 1 in the reaction space 25 and a rotating means, not shown, for rotating the semiconductor wafer 1 around the central axis at a predetermined speed.

The wafer support 40 is provided with an annular wafer support member 40a, corresponding to the wafer support member 2, supporting the periphery of the semiconductor wafer 1 and a stage 40b for supporting the wafer support member 40a. A plurality of radiation thermometers (pyrometers) 50 are buried in the stage 40b. The radiation thermometers 50 are connected to a controller 60 which is a computer, and the controller 60 controls a plurality of halogen lamps 70 based on the temperature information of the wafer obtained from the radiation thermometers 50.

The plurality of halogen lamps 70 are disposed above the quartz window 20c, configured to send the thermal energy toward the reaction space 25 through the quartz window 20c, and are arranged in a hexagonal pattern in plan view, for example. Each of the halogen lamps 70 is connected to a heating assembly base 90 for electrical connection to the power supply 80, respectively. A lamp voltage is applied to each halogen lamp 70 from the power supply 80, and the value of the lamp voltage is controlled by the controller 60.

When the semiconductor wafer 1 is subjected to the RTA treatment using the RTP apparatus 10 described above, the semiconductor wafer 1 is introduced into the reaction space 25 through the slit valve door (not shown) provided on the chamber 20 and is placed on the wafer support member 40a. Then, a gas is introduced through the gas inlet 20d, and lamp irradiation is performed on the wafer surface from the halogen lamp 70 under the control of the controller 60, while rotating the semiconductor wafer 1 using the rotation means.

The temperature control in the reaction space 25 in the RTP apparatus 10 is performed by measuring the temperature of the semiconductor wafer 1 under the RTA treatment using the plurality of radiation thermometers 50 buried in the stage 40b and controlling the plurality of halogen lamps 70 based on the measured temperature. Specifically, the controller 60 measures the average temperature of a plurality of points on the wafer surface along the radial direction of the wafer of the bottom surface of the semiconductor wafer 1 using the radiation thermometers 50, and performs the automatic control based on the measured temperature, (such as individual ON-OFF control of each lamp, increase/decrease control of the supplied power, and control of the intensity of the emitted light) of the halogen lamps 70 such that the in-plane temperature is approximately uniform throughout the process of heating and cooling in the RTA treatment.

### Details of RTA Treatment

In the present embodiment, the RTA treatment is performed using the RTP apparatus 10 under the condition of holding at a maximum temperature reached of 1250° C. or higher, or preferably 1300° C. or higher and 1350° C. or lower, for a period of 1 s or longer and 60 s or shorter in an oxidizing atmosphere and cooling to 1000° C. or lower at a cooling rate of 75° C./s or more and 120° C./s or less. This produces semiconductor wafers with sufficient gettering performance against metal impurities.

In addition, in the present embodiment, the first correction and the second correction are performed to the automatic control in the RTA treatment under the above condition. Specifically, in order to achieve higher wafer quality, the first correction is performed to eliminate the temperature variations of the entire semiconductor wafer 1 while performing the above automatic control throughout the process of heating and cooling in the RTA treatment. (See FIG. 1A) Furthermore, the second correction is performed to the wafer outer circumference 1d in the cooling process as a countermeasure to prevent slips due to performing the RTA treatment at a temperature of 1250° C. or higher (slips due to the thermal stress). (See FIG. 1B)

In more detail, the control of the controller 60 is used to set the first offset, which is the correction value of the temperature to eliminate the temperature variations on the entire plane of the semiconductor wafer 1 is set, with reference to the thickness of the oxidation layer formed on the wafer after performing the RTA treatment has been carried out in advance in an oxidizing atmosphere and to the strain-area ratio of the wafer measured with scanning infrared depolarization (SIRD), and the correction to the wafer temperature calculated by each pyrometer 50 (the first correction) is carried out entirely throughout the heating and cooling process of the RTA treatment. This allows to reduce the temperature difference occurring in the wafer plane throughout the RTA treatment process and to control the variation of the thermal stress and the BMD density.

A known method may be used to determine the first offset, and specifically, the techniques set forth in JP-A-2002-043227 or the Japanese translation of PCT International Application No. 2002-522912 (WO/2000/009976) may be used. In the present embodiment, for example, the first offset is determined using any one or more of the techniques set forth in the above documents.

In the cooling process, while performing the above-described automatic control and the first correction, the second correction is made to the wafer outer circumference 1d, which is the region within 10 mm toward the center from the periphery of the semiconductor wafer 1, or the region 140 mm to 150 mm from the center of the wafer for the case of 300 mm diameter, for example, with the temperature correction range of +0.1° C. or more and +5.0° C. or less, more preferably +0.3° C. or more and +3.0° C. or less, and particularly preferably +1.0° C. or more and +1.5° C. or less. That is, the second offset, which is the temperature correction value of +0.1° C. or more and +5.0° C. or less, is set in advance, by the control of the controller 60. In the process of rapid cooling from the maximum temperature reached (cooling process), since the wafer outer circumference 1d, which is the wafer edge surface, is likely more heat-dissipated than at the center of the wafer, the thermal stress generated in the cooling process can be suppressed to the minimum level by performing the temperature correction to the wafer temperature calculated from the readings from the pyrometer 50 at the position of the wafer outer circumference 1d. As a result, the slips due to the thermal stress can also be suppressed to the minimum level. (See FIG. 1C) For example, when the second offset is less than +0.1° C., it is unfavorable because the thermal stress due to the heat-dissipation of the wafer outer circumference 1d is not sufficiently suppressed. When the second offset exceeds +5.0° C., more heat is introduced than heat-dissipated to the wafer outer circumference 1d; as a result, it is not favorable because slips due to thermal stress are generated.

The second correction described above provides sufficient slip suppression effects if, in the cooling process, the second correction is performed at least during the period from the start of cooling until 5 seconds have elapsed (immediately after the end of the heating process, including the holding time at the maximum temperature reached), i.e. it is performed for 5 s from the start of cooling. For example, if the second correction is not performed during this period, it is not desirable because thermal stress due to heat dissipation in the wafer outer circumference id cannot be adequately suppressed. Meanwhile, the second correction is only to be performed for at least 5 s from the start of cooling; for example, it can be performed continuously after 5 s elapsed from the start of cooling if it is during the cooling process.

In the RTA treatment of the present embodiment, during the cooling process, while the automatic control and the first correction described above are being performed, further the second correction of +0.5° C. or more and +5.0° C. or less is performed to the wafer outer circumference 1d, but not limited thereto. For example, in the second correction, in the cooling process, the temperature correction value for the wafer outer circumference 1d can be within relatively +0.5° C. or more and +5.0° C. or less, when compared to the temperature correction value for the other area of the wafer (the wafer region from the center of the wafer to the wafer outer circumference 1d). The second offset may be preset by the control of the controller 60 so as to satisfy the condition.

For one example, during the cooling process, while the automatic control and the first correction described above are being performed, further, the correction (the second correction) to the area other than the wafer outer circumference 1d of the semiconductor wafer 1 (the area from the center of the wafer to 140 mm of the wafer for the case of a 300 mm diameter wafer) is set to within −5.0° C. or more and −0.1° C. or less, preferably within −3.0° C. or more and −0.5° C. or less, or particularly preferably within −1.5° C. or more and −1.0° C. or less can be considered. As a result, similar to the above, by minimizing the thermal stress that occurs during the cooling process, slips due to thermal stress can be minimized.

It is preferable that in the RTA treatment of the present embodiment, during the cooling process, while the automatic control and the first correction described above are being performed, the second correction of +0.5° C. or more and +5.0° C. or less is performed to the entire wafer outer circumference 1d. However, for example, other methods may be applied according to such as the characteristics of the required semiconductor wafers 1. Specifically, during the cooling process, while the automatic control and the first correction described above are being performed, the second correction of +0.1° C. or more and +5.0° C. or less, preferably +0.5° C. or more and 3.0° C. or less, particularly preferably +1.0° C. or more and +1.5° C. or less is performed on a part of the wafer outer circumference 1d, such as only the periphery of the wafer, or the wafer outer circumference excluding for the wafer periphery. Since the thermal stress occurring in the cooling process is suppressed by the second correction as well, slip-inhibiting effects can be obtained.

The method of manufacturing semiconductor devices of the present embodiment includes a process for performing the RTA treatment on semiconductor wafers, and the manufacturing process of semiconductor devices can use a known conventional method, for example. In the process of performing the RTA treatment described above on semiconductor wafers throughout the entire process from heating to cooling, the first correction is performed using the first offset which is the temperature correction to eliminate the temperature variations over the entire wafer surface. Furthermore, during the cooling process, the second correction is performed which is the temperature correction using the second offset which is set so that the temperature correction value for the wafer outer circumference, which is the wafer outer circumference including the wafer periphery, is relatively set between +0.1° C. or more and +5.0° C. or less, preferably +0.5° C. or more and 3.0° C. or less, particularly preferably +1.0° C. or more and +1.5° C. or less, relative to the temperature correction values for the wafer regions other than the wafer outer circumference. Accordingly, by performing the temperature correction, the thermal stress occurring during the cooling process is minimized, and the slips due to the thermal stress are suppressed to a minimum.

Also in the method of manufacturing semiconductor devices of the present embodiment, during the cooling process, while the automatic control and the first correction described above are being performed, the second correction of +0.1° C. or more and +5.0° C. or less, preferably +0.5° C. or more and 3.0° C. or less, particularly preferably +1.0° C. or more and +1.5° C. or less may be performed on a part or the whole of the wafer outer circumference 1d which is such as only the periphery of the wafer or the outer circumferential region except for the wafer periphery. Since the thermal stress occurring in the cooling process is suppressed by the second correction as well, slip-inhibiting effects can be obtained.

### EMBODIMENTS

The method of manufacturing semiconductor wafers according to the present invention will be further described based on the embodiments. However, the invention is not limited to these embodiments.

### Manufacturing of Semiconductor Wafers for the RTA Treatment

Fifty silicon wafers with a diameter of 300 mm were produced by applying the above-described manufacturing processes of beveling, lapping, grinding, and etching to wafers which are obtained by slicing a silicon single crystal ingot with an oxygen concentration of 1.0×10¹⁸/cm³. The silicon wafers produced by the manufacturing process were formed so that the angle between the wafer backside and the backside bevel was obtuse and processed so that the apex of the obtuse angle came into contact with the support surface inclined downward toward the inside (corresponding to the semiconductor wafer 1 in FIG. 1A) when the silicon wafer was mounted on the wafer support member prepared inside the RTP apparatus. The surface roughness of the silicon wafer in the vicinity of the contact area of the silicon wafer with the wafer support member was Ra=20 nm.

### Experimental Example 1

Ten out of the fifty silicon wafers thus produced were used. The silicon wafer was subjected to the RTA treatment one by one according to the method of Experimental Example 1 (see FIGS. 1A through 1C) while the silicon wafer was mounted on the wafer support member prepared inside the RTP apparatus. The RTP apparatus shown in FIG. 2 was used.

Specifically, in the method of Experimental Example 1, with reference to the thickness of the oxide formed on the wafer after the RTA treatment in an oxidizing atmosphere and the strain-area ratio of the wafer by SIRD, the first offset, which is the temperature correction value to eliminate the temperature variations over the entire wafer, was set in advance. In addition, under this circumstance, the RTA treatment was performed on each of the silicon wafers under the conditions of holding at a maximum temperature reached of 1350° C. for a period of 30 s in an oxidizing atmosphere and cooling down to 1000° C. or less at a cooling rate of 120° C./s. In the above procedure, a correction was made to the wafer temperature calculated using the readings from the pyrometers at positions from the center of the wafer to 140 mm to 150 mm in a period up to 5 s elapsed from the start time of cooling (immediately after the end of the heating process). (A second offset was preset on the RTP apparatus.) The second offset was set to +0.5° C. based on the first offset.

### Experimental Example 2

Ten out of the remaining forty silicon wafers were used. The silicon wafer was subjected to the RTA treatment one by one according to the method of Experimental Example 2 (see FIGS. 1A through 1C) while the silicon wafer was mounted on the wafer support member prepared inside the RTP apparatus. The method of Experimental Example 2 is the same as that of Experimental Example 1 except for the value of the second offset. The second offset in the method of Experimental Example 2 was set to +1.0° C. based on the first offset.

### Experimental Example 3

Ten out of the remaining thirty silicon wafers were used. The silicon wafer was subjected to the RTA treatment one by one according to the method of Experimental Example 3 while the silicon wafer was mounted on the wafer support member prepared inside the RTP apparatus. The method of Experimental Example 3 is the same as that of Experimental Example 1 except for the value of the second offset. The second offset in the method of Experimental Example 3 was set to +1.5° C. based on the first offset.

### Experimental Example 4

Ten out of the remaining twenty silicon wafers were used. The silicon wafer was subjected to the RTA treatment one by one according to the method of Experimental Example 4 while the silicon wafer was mounted on the wafer support member prepared inside the RTP apparatus. The method of Experimental Example 4 is the same as that of Experimental Example 1 except for the value of the second offset. The second offset in the method of Experimental Example 4 was set to +2.0° C. based on the first offset.

### Comparative Example 1

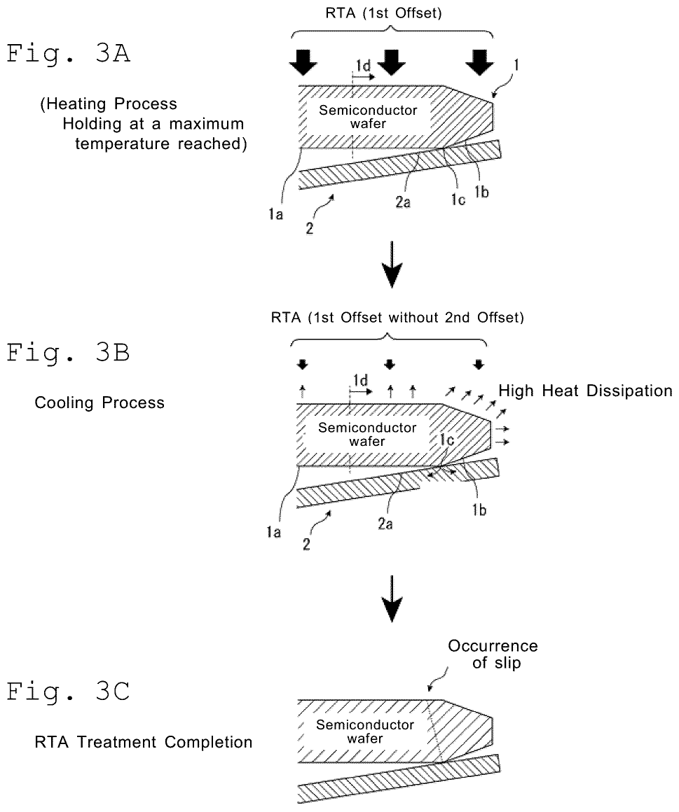

Ten remaining silicon wafers were used. The silicon wafer was subjected to the RTA treatment one by one according to the method of Comparative Example 1 (see FIG. 3A through 3C) while the silicon wafer was mounted on the wafer support member prepared inside the RTP apparatus. The method of Comparative Example 1 is the same as that of Experimental Example 1 except for not performing the second offset. That is, the cooling process in FIG. 3B differs from that in FIG. 1B.

### Evaluation Method

SIRD measurements were performed on each of the silicon wafers after the RTA treatment, and the slips and the strain-area ratio were evaluated. The ratio (strain-area ratio) of the area where the strain stress was increased due to slips to the total area of the silicon wafer was calculated and evaluated. For example, the larger the strain area ratio, the worse the slip quality, and the smaller the strain area ratio, the better the slip quality.

### Evaluation Results

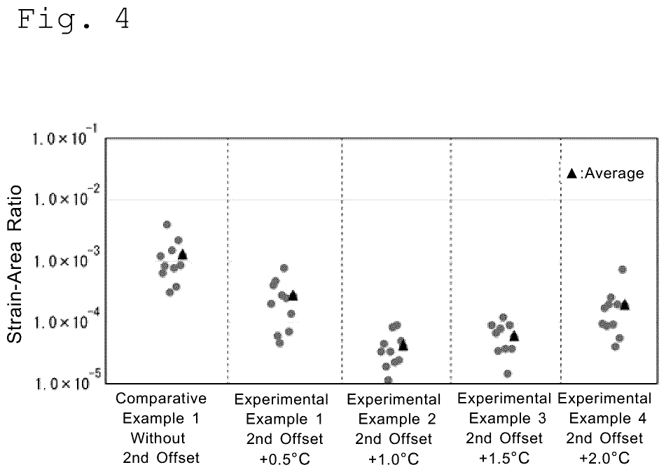

FIG. 4 is a figure showing the measurement results by SIRD of the strain-area ratio of each silicon wafer subjected to the RTA treatment by the method of Experimental Examples 1 to 4 and Comparative Example 1. The silicon wafers subjected to the RTA treatment with the method of Comparative Example 1 (i.e. without the second offset) show an average strain-area ratio of 1.2×10⁻³, and in which slips due to thermal stress occurred most frequently at the wafer edge surface. In other words, results were obtained that in the cooling process of Comparative Example 1, the wafer edge surface is more susceptible to heat dissipation than the wafer center, and in addition, the heat transfer from the wafer edge surface to the wafer support member and the self-weight stress of the wafer combined are likely to cause slips (see FIGS. 3A-3C).

Meanwhile, the silicon wafers subjected to the RTA treatment with the method of Experimental Example 1 (the second offset was +0.5° C.) showed an average strain-area ratio of 2.6×10⁻⁴, and the silicon wafers subjected to the RTA treatment with the method of Experimental Example 4 (the second offset was +2.0° C.) showed an average strain-area ratio of 1.9×10⁻⁴; in those cases, slips were more suppressed than those subjected to the RTA treatment with the method of Comparative Example 1.

In addition, the silicon wafers subjected to the RTA treatment with the method of Experimental Example 2 (the second offset was +1.0° C.) and with the method of Experimental Example 3 (the second offset was +1.5° C.) have an average strain-area ratio of 4.1×10⁻⁵ and 5.7×10⁻⁵, respectively, it is found that the average strain-area ratios are very small and the slips are suppressed. Further, it is confirmed that the strain-area ratio at the wafer edge surface decreases by approximately 96% when compared to the silicon wafers subjected to the RTA treatment by the method of Comparative Example 1 (without the second offset).

### REFERENCE SIGNS LIST

1 Semiconductor wafer
1a wafer backside
1b backside bevel
1c apex
1d wafer outer circumference
2 wafer support member
2a support surface
10 RTA apparatus
20 chamber
20a chamber wall
20b chamber bottom
20c quartz window
20d gas inlet
20e gas outlet
25 reaction space
30 gas supply source
31 vacuum pump
40 wafer support
40a wafer support member
50 radiation thermometer (pyrometer)
60 controller
70 halogen lamp
80 power supply
90 heating assembly base

What is claimed is:

1. A method of manufacturing a semiconductor wafer including a step of performing an RTA treatment, comprising:
a step of performing a first correction using a first offset which is a temperature correction value for eliminating temperature variations over the entire wafer surface throughout the entire processes from heating to cooling in the RTA treatment; and
a step of further performing a second correction using a second offset in the cooling process, which is a temperature correction value being set so that the temperature correction value for a wafer outer circumference, which is the outer circumferential region including the wafer periphery, is set to be relatively +0.1° C. or more and +5.0° C. or less, compared to the temperature correction values for the wafer regions other than the wafer outer circumference.

2. The method of manufacturing a semiconductor wafer of claim 1, wherein
the second correction of +0.1° C. or more and +5.0° C. or less is performed to part or the entire wafer outer circumference.

3. The method of manufacturing a semiconductor wafer of claim 1, wherein
the RTA treatment is carried out in an oxidizing atmosphere under conditions of holding at a maximum temperature reached of 1250° C. or higher for a period of 1 s or more and 60 s or less and of cooling down to 1000° C. or less at a cooling rate of 75° C./s or more and 120° C./s or less.

4. The method of manufacturing a semiconductor wafer of claim 1, wherein
the second correction is performed within a period of at least 5 s of the elapsed time from the time of the start of cooling in the cooling process.

5. The method of manufacturing a semiconductor wafer of claim 1, wherein
the RTA treatment is performed while the semiconductor wafer is placed on a wafer support member having a support surface inclined downwardly toward the inside, and the surface roughness of the semiconductor wafer in the vicinity of the contact position of the semiconductor wafer with the wafer support member is 5.0 nm≤Ra≤30.0 nm.

6. The method of manufacturing a semiconductor wafer of claim 1, wherein
the diameter of the semiconductor wafer subjected to the RTA treatment is 300 mm or more.

7. The method of manufacturing a semiconductor wafer of claim 1, wherein
the wafer outer circumference is defined as an area of 10 mm or less to the center from the periphery of the semiconductor wafer.

8. A method of manufacturing a semiconductor device, comprising:
a step of an RTA treatment comprising a heating process and a cooling process on a semiconductor wafer;
a step of performing a first correction using a first offset which is a temperature correction value to eliminate temperature variations over the entire wafer surface throughout the entire process from heating to cooling in the RTA treatment; and
a step of further performing a second correction using a second offset in the cooling process, which is temperature correction value being set so that the temperature correction value for the wafer outer circumference, which is the outer circumferential region including the wafer periphery, is set to be relatively +0.1° C. or more to +5.0° C. or less, compared to the temperature correction values for the wafer regions other than the wafer outer circumference.

9. The method of manufacturing a semiconductor device of claim 8, wherein
the second correction of +0.1° C. or more and +5.0° C. or less is performed to part or the entire wafer outer circumference.
